(19) United States
(12) Patent Application Publication
(10) Pub. No.: US 2022/0070590 A1
(43) Pub. Date: Mar. 3, 2022

(54) PIEZORESISTIVE MICROPHONE WITH ARC-SHAPED SPRINGS

(71) Applicant: SEOUL NATIONAL UNIVERSITY R&DB FOUNDATION, Seoul (KR)

(72) Inventors: Dong Il CHO, Seoul (KR); Bobaro CHANG, Seoul (KR); Ailian JIN, Seoul (KR); Tae Yup KIM, Anyang-si (KR); Junghyun PARK, Seoul (KR)

(21) Appl. No.: 17/037,242

(22) Filed: Sep. 29, 2020

(30) Foreign Application Priority Data
Aug. 31, 2020 (KR) 10-2020-0110234

(51) Int. Cl. H04R 17/02; H01L 41/113; G01L 9/00; H01L 29/06

(52) U.S. Cl. CPC H04R 17/025; H01L 29/0669; G01L 9/0055; H01L 41/1132

(57) ABSTRACT

The present disclosure relates to a design method for a piezoresistive-sensing-type microphone with an arc-shaped spring structure for ultra-miniaturization and high sensitivity. With the addition of the spring structure to the membrane, it is possible to minimize the membrane that has greater area for high sensitivity, and further, it is possible to minimize the area while providing the same effect as beam-shape springs and serpentine springs through an arc-shape spring design. A piezoresistor such as silicon nanowires with good piezoresistive properties as a sensing element is included in the spring structure to achieve high sensitivity, and the piezoresistor is placed in the spring structure at each location where the maximum tension occurs and where the maximum compression occurs through simulation. This allows both single-mode and differential-mode measurement, thereby ensuring the maximum resistance change and SNR.

### DESCRIPTION OF GOVERNMENT-FUNDED RESEARCH AND DEVELOPMENT

This research is funded by nanomaterials technology development project (Development of bulk silicon SOLID NEMS process platform for smart sensors, Project No. 1711105889, Serial No. 2015M3A7B7046616), Ministry of Science and ICT, Republic of Korea.

### CROSS-REFERENCE TO RELATED APPLICATION

This application claims priority to Republic of Korean Patent Application No. 10-2020-0110234, filed on Aug. 31, 2020, and all the benefits accruing therefrom under 35 U.S.C. § 119, the contents of which in its entirety are herein incorporated for reference.

### BACKGROUND

### 1. Field

The present disclosure relates to a piezoresistive microphone, and in particular, to a microphone with a spring structure surrounding at least a part of its membrane and a piezoresistor such as silicon nanowires implemented in the spring structure to achieve sensitivity improvement and sensor miniaturization.

### 2. Description of the Related Art

Many types of microphones, such as the capacitive type, piezoelectric type and piezoresistive type, have been developed based on different sensing principles using various Micro-Electro-Mechanical System processes.

The capacitive-sensing-type microphone with thin-film electrodes that are subjected to pressure has the disadvantage of high process complexity in that many wafers have to be bonded or many masks have to be used implement the thin-film electrodes with spacing. Additionally, when considering that thin-film electrodes of commercially available sensors deform by a few micrometers, the capacitive-sensing-type microphone should have a minimum thin-film size of about 700 μm×700 μm for 1 pF nominal capacitance change. This imposes limitations on sensor miniaturization.

The piezoelectric-sensing-type microphone may be produced by a process that involves fabricating an insulating film on a silicon substrate, a lower electrode, a piezoelectric layer, and an upper electrode in that order, and then etching the rear surface of the silicon substrate to float the components. The piezoelectric-sensing-type microphone outputs a change in voltage that occurs in proportion to the sound pressure applied to the piezoelectric layer to an external amplifier through the upper and lower electrodes. In the piezoelectric-sensing-type microphone, the piezoelectric layer acts as a membrane. Thus, to achieve high sensitivity, the membrane needs to be big which a drawback is. Additionally, owing to limitations in machining the material of the piezoelectric layer in the form of a thin-film, the fabrication of this type of microphone involves high process complexity. Another disadvantage is its unstable characteristics in low-frequency signal measurement.

The piezoresistive-sensing-type microphone has a piezoresistor. The resistance of the piezoresistor changes when pressure is applied to a membrane made of polycrystalline silicon, silicon nitride, etc. Compared to the capacitive and piezoelectric-sensing-type microphones, the piezoresistive-sensing-type microphone has advantages in terms of minimization, high sensitivity, low process complexity, and applicability without being limited to a particular frequency response. However, the piezoresistor is usually positioned in the membrane, and it deforms only in response to vibration of the membrane. That is, to increase the sensitivity by maximizing the deformation of the piezoresistor, it is necessary to increase the size of the membrane to allow the membrane to deform to a greater extent; thus, there are limitations in the miniaturization of this type of microphones.

### SUMMARY

The present disclosure is designed to solve the abovementioned problem, and therefore, the present disclosure is directed to developing a microphone with a spring structure positioned surrounding at least a part of its membrane and a piezoresistor such as silicon nanowires implemented in the spring structure to achieve sensitivity improvement and sensor miniaturization.

A piezoresistive-sensing-type microphone according to the embodiment of the present disclosure includes a membrane, a spring structure that surrounds at least a part of the membrane, with sufficient spacing from the membrane, at least one first connecting part that connects the membrane to the spring structure, an anchor structure that surrounds at least part of the spring structure, with sufficient spacing from the spring structure, at least one second connecting part that connects the anchor structure to the spring structure, at least one piezoresistor formed on the spring structure, and at least one electrode positioned on the anchor structure to sense an electrical signal based on a change in the resistance of the piezoresistor. The membrane, spring structure, first connecting part and second connecting part can move in air through a cavity formed below in the anchor structures.

In the resulting microphone, the flexible spring structure undergoes deformation because of the external sound pressure, and the nanowire-based piezoresistor is positioned in the area of the spring structure corresponding to the maximum stress point or in the vicinity of the maximum stress point. That is, considering the piezoresistive a property, the piezoresistor is positioned at or near the location where the maximum stress is generated, thereby obtaining the maximum gauge change efficiency.

Additionally, the resulting microphone according to this embodiment is based on the characteristics that a change in resistance changes in polarity depending on the type of stress generated. The piezoresistor is positioned at or near each of the maximum tension point and the maximum compression point of the spring structure to obtain differential-mode signal measurements, thereby ensuring a high signal to noise ratio (SNR).

Additionally, the resulting microphone may provide higher sensitivity owing to the spring structure without any increase in the size of the membrane; thus, from the viewpoint of minimization, it may be advantageous over the traditional microphone with no spring structure in which the entire outer periphery of the membrane is attached to the substrate.

### BRIEF DESCRIPTION OF THE DRAWINGS

FIG. 1 shows a perspective view of a piezoresistive microphone according to the embodiment of the present disclosure.

FIG. 2 shows a magnified view of FIG. 1 according to the embodiment of the present disclosure.

FIG. 3 shows a rear view of a piezoresistive microphone according to the embodiment of the present disclosure.

FIG. 4 shows a front view of a piezoresistive microphone according to the embodiment of the present disclosure.

FIGS. 5 and 6 show the magnified views of FIG. 4 according to the embodiment of the present disclosure.

FIG. 7 shows simulation results of the von-Mises stress distribution in the vibration of the membrane of the microphone according to the embodiment of the present disclosure.

FIG. 8 shows simulation results of the von-Mises stress distribution generated with a downward movement of the membrane of the microphone according to an embodiment of the present disclosure.

FIG. 9 shows a graph of the change in the von-Mises stress observed in the membrane and the spring structure corresponding to A-A′ in FIG. 7 under a sound pressure of 50 dB spl to 120 dB spl inputted to the microphone.

### DETAILED DESCRIPTION

The following detailed description of the present disclosure is made with reference to the accompanying drawings, in which particular embodiments for practicing the present disclosure are illustrated. The embodiments of the detailed description are provided for a sufficiently detailed disclosure so that those skilled in the art can practice the present disclosure.

Although each embodiment of the present disclosure may differ from that described herein, it does not mean that the embodiments are mutually exclusive. For example, particular shapes, structures, and features described in connection with an embodiment of the detailed description may be equally embodied in other embodiment without departing from the spirit and scope of the present disclosure. Additionally, it should be understood that a variety of changes may be made to the positions or placements of individual elements in each disclosed embodiment without departing from the spirit and scope of the present disclosure. The size of each element in the accompanying drawings may be exaggerated for description and does not need to be equal or similar to the actual size.

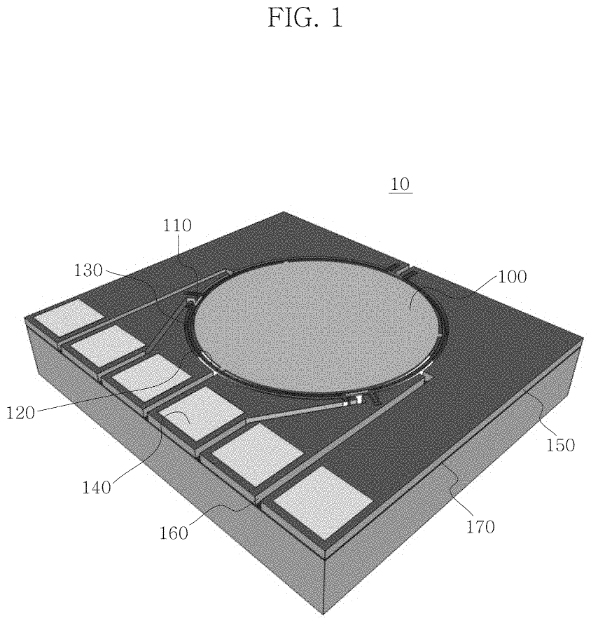

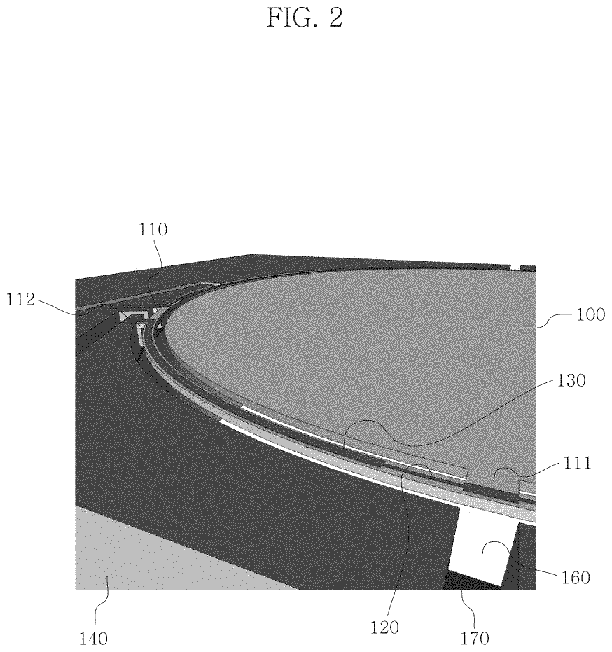

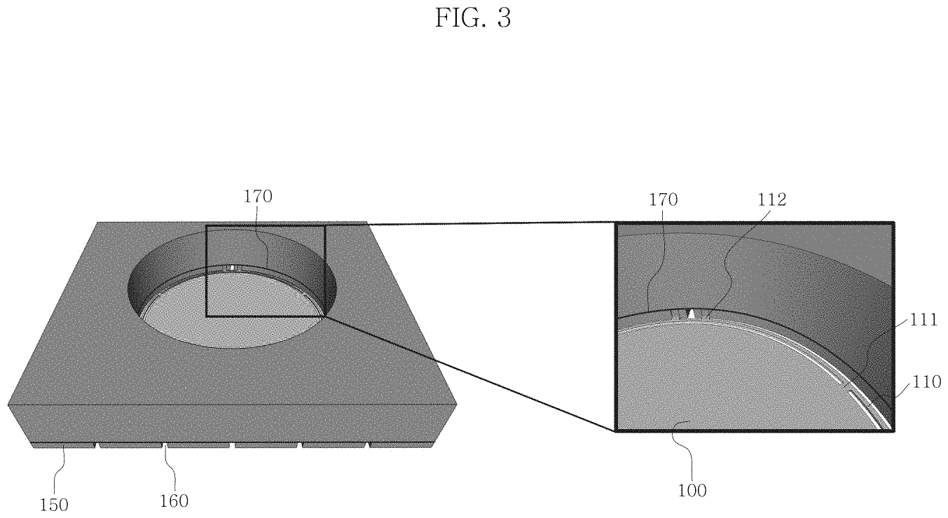

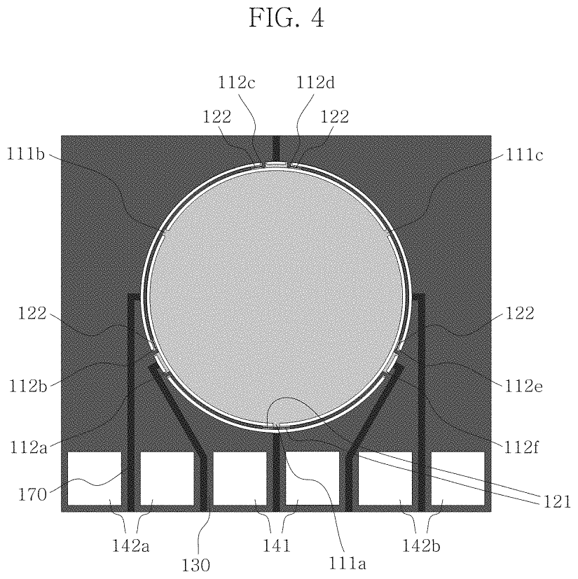

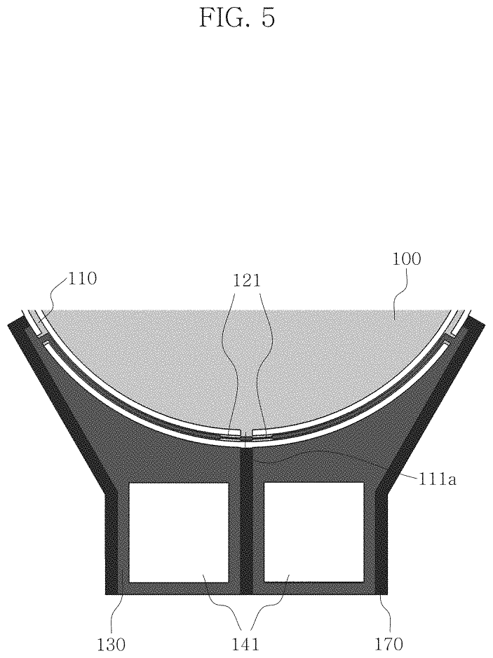

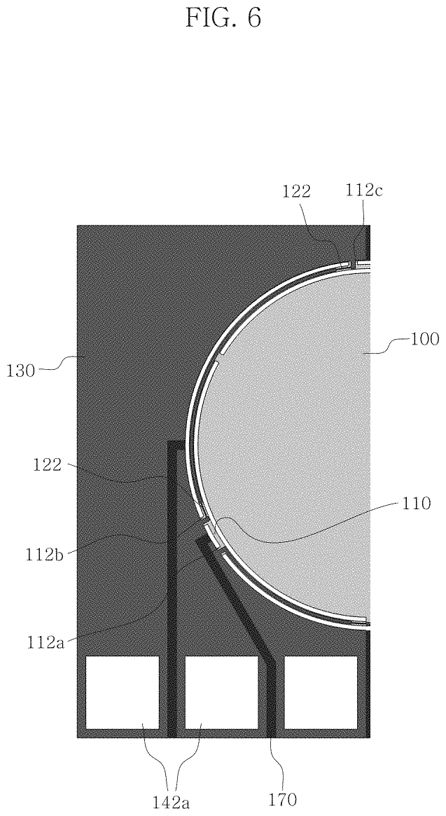

FIG. 1 shows a perspective view of a piezoresistive microphone according to an embodiment of the present disclosure. FIG. 2 shows a magnified view of FIG. 1. FIG. 3 shows a rear view of the piezoresistive microphone according to an embodiment of the present disclosure. FIG. 4 shows a front view of the piezoresistive microphone according to an embodiment of the present disclosure. FIGS. 5 and 6 show magnified views of FIG. 4.

Referring to FIGS. 1 to 6, piezoresistive microphone 10 according to an embodiment of the present disclosure includes membrane 100, spring structure 110, piezoresistor 120, sensor structure pattern 130, electrode 140, anchor structure 150, insulation pattern 160 and oxide film 170.

Membrane 100 may be configured to vibrate in response to the externally applied sound pressure. Membrane 100 may be fixed to anchor structure 150 through spring structure 110, and it may move up and down in response to the sound pressure.

Spring structure 110 may be spaced a predetermined distance from membrane 100 and configured to surround at least part of membrane 100. That is, spring structure 110 may have a shape corresponding to that of membrane 100 and may be configured to surround the whole or part of membrane 100 separated by a specific distance from membrane 100. As shown in FIG. 1, membrane 100 may be circular, and spring structure 110 may be shaped as a ring that surrounds entire membrane 100, but is not limited thereto. Spring structure 110 may be arc shaped to surround a part of membrane 100, and a plurality of arc-shaped spring structures 110 may be configured to surround entire membrane 100.

Spring structure 110 and membrane 100 may be connected through first connecting part 111. Spring structure 110 may extend with a predetermined width along the circumference of membrane 100. First connecting part 111 may protrude from spring structure 110 to membrane 100 in a direction different from that in which spring structure 110 extends and may connect membrane 100 to spring structure 110. At least one first connecting part 111 may connect membrane 100 to spring structure 110. As shown in FIG. 4, circular membrane 100 and ring-shaped spring structure 110 surrounding circular membrane 100 may be connected through three first connecting parts 111a, 111b, and 111c. Three first connecting parts 111a, 111b, and 111c may be positioned such that the angle between the adjacent first connecting parts is 120°. The vibration of membrane 100 may be transmitted to spring structure 110 through first connecting part 111. That is, the stress caused by the movement of membrane 100 is generated in spring structure 110 through first connecting part 111.

Spring structure 110 may be connected and supported by anchor structure 150. Anchor structure 150 may be configured to surround at least a part of spring structure 110, and separated from spring structure 110. Anchor structure 150 may define a circular internal space that surrounds ring-shaped spring structure 110. Anchor structure 150 and spring structure 110 may be connected through second connecting part 112 that may protrude from spring structure 110 to anchor structure 150 in a direction different from that in which spring structure 110 extends. Second connecting part 112 may connect anchor structure 150 to spring structure 110. As shown in FIG. 4, anchor structure 150 and ring-shaped spring structure 110 may be connected through six second connecting parts 112a, 112b, 112c, 112d, 112e, and 112f.

Anchor structure 150 may support spring structure 110 through second connecting part 112, and spring structure 110 may support membrane 100 through first connecting part 111. Anchor structure 150 may support membrane 100 and spring structure 110 such that membrane 100 and spring structure 110 float in the air. As shown in FIG. 3, a cavity may be formed in anchor structure 150. Membrane 100, spring structure 110, first connecting part 111 and second connecting part 112 may be free to move in air because of the cavity formed in anchor structure 150. Membrane 100 and spring structure 110 floating in the air may vibrate because of external sound pressure.

In microphone 10 according to an embodiment of the present disclosure, piezoresistor 120 was formed in spring structure 110, not in membrane 100.

When external sound pressure is introduced through the cavity located below membrane 100, membrane 100 and spring structure 110 vibrate. Because of a difference in stiffness between the two structures, most of the deformation is distributed in flexible spring structure 110. That is, the narrow spring structure 110 formed along the circumference of membrane 100 deforms to a greater extent than membrane 100; thus, the maximum stress point is located in spring structure 110. Piezoresistor 120 positioned in spring structure 110 may be subjected to a higher stress than when positioned in membrane 100. A change in resistance occurs because of the piezoresistive effect of piezoresistor 120 caused by stress and sound pressure may be sensed as an electrical signal based on the change in resistance.

Sensor structure pattern 130 may be formed on second connecting part 112 and spring structure 110 such that sensor structure pattern 130 is electrically connected to piezoresistor 120 to transmit the change in resistance of piezoresistor 120. Sensor structure pattern 130 may be also formed on anchor structure 150 such that sensor structure pattern 130 is connected to the electrode 140. Piezoresistor 120 may be a very narrow silicon nanowire with a predetermined length, and sensor structure pattern 130 may be a silicon-based structure wider than the silicon nanowire.

Membrane 100 and spring structure 110 may be formed by a silicon nitride layer or a composite layer with a silicon nitride layer and a dielectric thin-film (silicon oxide, silicon rich nitride, silicon dioxide, polysilicon, etc.). As shown in FIG. 4, sensor structure pattern 130 and piezoresistor 120 may be formed on spring structure 110, but the present disclosure is not limited thereto. Sensor structure pattern 130 and piezoresistor 120 may be embedded in spring structure 110.

Electrode 140 may be formed on anchor structure 150 and electrically connected to sensor structure pattern 130. An electrical signal arising from the change in the piezoresistor 120 may be sensed through electrode 140. Additionally, anchor structure 150 may further include insulation pattern 160 for insulation between adjacent sensor structure patterns 130 and between adjacent electrodes 140. Insulation pattern 160 may spatially separate adjacent sensor structure patterns 130 and adjacent electrodes 140. Insulation pattern 160 may be formed with sufficient width and height to spatially separate adjacent sensor structure patterns 130 and adjacent electrodes 140. For example, insulation pattern 160 is formed with a predetermined height, and oxide film 170 is formed below insulation pattern 160 to further provide an electrical insulation effect. However, the present disclosure is not limited thereto, and insulation pattern 160 may be formed such that its height corresponds to the total thickness of anchor structure 150.

Oxide film 170 may be buried in anchor structure 150 in the form of buried oxide (BOX). It may electrically separate electrodes 140 adjacent to each other. Additionally, it is possible to achieve insulation between the upper and lower areas of anchor structure 150 using oxide film 170.

Here, most of the deformation caused by the sound pressure is distributed in spring structure 110, and the deformation induced by compression and tension may simultaneously occur in spring structure 110 in response to sound pressure. The former deformation refers to the generated stress that results in tension in piezoresistor 120, and the latter deformation refers to generated stress that results in tension in piezoresistor 120. First connecting part 111 may be connected to spring structure 110 and membrane 100, and second connecting part 112 may be connected to spring structure 110 and anchor structure 150, to cause simultaneous compression-induced and tension-induced deformation in spring structure 110 in response to the external sound pressure. That is, when membrane 100 moves in one direction in response to the sound pressure, first connecting part 111 and second connecting part 112 may be positioned so that a part of spring structure 110 moves in one direction along with membrane 100 and is subjected to compression, and the remaining part of spring structure 110 is fixed to anchor structure 150, and subjected to tension. For example, first connecting part 111 and second connecting part 112 may be positioned symmetrically with respect to an imagery line passing through the center of membrane 100. That is, as shown in FIG. 4, first connecting part 111a and second connecting parts 112c and 112d may be symmetrically arranged; Similarly, first connecting part 111b and second connecting parts 112e and 112f may be symmetrically set; and first connecting part 111c and second connecting parts 112a and 112b may be arranged symmetrically. With the symmetrical arrangement of first connecting parts 111 and second connecting parts 112, deformation may be induced by compression and tension simultaneously in spring structure 110 in response to the external sound pressure.

For example, when membrane 100 moves in one direction in response to sound pressure, compression-induced deformation may occur at spring structure 110 connected to first connecting part 111, while tension-induced deformation may occur at spring structure 110 that is connected to second connecting part 112. In contrary, when membrane 100 moves in a direction different from the abovementioned direction in response to the sound pressure, tension-induced deformation may occur at spring structure 110 connected to first connecting part 111, while compression-induced deformation may occur simultaneously at the spring structure 110 connected to second connecting part 112. That is, with the symmetrical arrangement of first connecting part 111 and second connecting part 112 that connects spring structure 110 to the other component, different types of stresses occur around the connecting parts in spring structure 110.

The change in resistance of piezoresistor 120 changes in polarity depending on compression-induced deformation and tension-induced deformation. For example, piezoresistor 120 may output a positive electrical signal change in response to compression-induced deformation, and a negative electrical signal change in response to tension-induced deformation.

The electrode 140 is configured to sense the change in resistance according to the compression-induced deformation or tension-induced deformation of the piezoresistor 120. The piezoresistive microphone 10 can provide a single mode of outputting a deformation of the piezoelectric resistor 120 to which each electrode 140 is electrically connected. However, the present disclosure is not limited thereto, and a differential mode using outputs of a different polarity output from the piezoresistor 120 may be provided as follows. That is, a single mode or a differential mode may be provided, and sensing sensitivity may be further increased according to the differential mode.

Piezoresistor 120 of the present disclosure includes first piezoresistor 121 and second piezoresistor 122 that exhibit a change in resistance with different polarities in response to the deformation of the spring structure 110. That is, when the change in resistance outputted from first piezoresistor 121 and second piezoresistor 122 is sensed, differential-mode signal measurement become possible, and a high SNR can be realized. Electrode 140 may include first electrode 141 configured to sense the deformation of first piezoresistor 121 and second electrode 142 configured to sense the deformation of second piezoresistor 122. First electrode 141 and second electrode 142 may output changes in voltage with different polarities, thereby allowing differential-mode signal measurement.

Each of first piezoresistor 121 and second piezoresistor 122 may be positioned at the location of spring structure 110 where different types of stresses are generated when spring structure 110 is deformed. For example, when tension-induced and compression-induced deformation occurs simultaneously in spring structure 110 in response to sound pressure, first piezoresistor 121 may be located in the region that undergoes tension-induced deformation, and second piezoresistor 122 may be located in the region that undergoes compression-induced deformation. First piezoresistor 121 may be located near spring structure 110 connected to first connecting part 111, and second piezoresistor 122 may be located in the area of the spring structure 110 connected to second connecting part 112. However, when multiple first connecting parts 111 and second connecting parts 112, are involved. First piezoresistor 121 and second piezoresistor 122 may be selectively positioned near spring structure 110 connected to first connecting parts 111 and second connecting parts 112 for the abovementioned differential-mode signal measurement.

FIG. 5 shows a magnified view of the electrical connection relationship between first piezoresistor 121 and first electrode 141. FIG. 6 shows a magnified view of the electrical relationship between second piezoresistor 122 and second electrode 142.

As shown in FIGS. 4 to 6, first piezoresistor 121 may be selectively located near spring structure 110 connected to first connecting part 111a so that first piezoresistor 121 is electrically connected to first electrode 141. Additionally, second piezoresistor 122 may be located near spring structure 110 connected to second connecting parts 112b and 112c so that second piezoresistor 122 is electrically connected to second electrode 142a, and second piezoresistor 122 may be located near spring structure 110 connected to second connecting parts 112d and 112e so that second piezoresistor 122 is electrically connected to second electrode 142b. That is, first piezoresistor 121 is not located near spring structure 110 connected to first connecting parts 111b and 111c, and second piezoresistor 122 is not located near spring structure 110 connected to second connecting parts 112a and 112f. As in the abovementioned structure, a positive voltage change may be outputted through first electrode 141 by compression-induced deformation of first piezoresistor 121, and a negative voltage change may be outputted through second electrodes 142a and 142b by tension-induced deformation of second piezoresistor 122. Here, each of the voltages outputted through second electrodes 142a and 142b can be compared with that outputted through first electrode 141, thereby allowing differential-mode signal measurements.

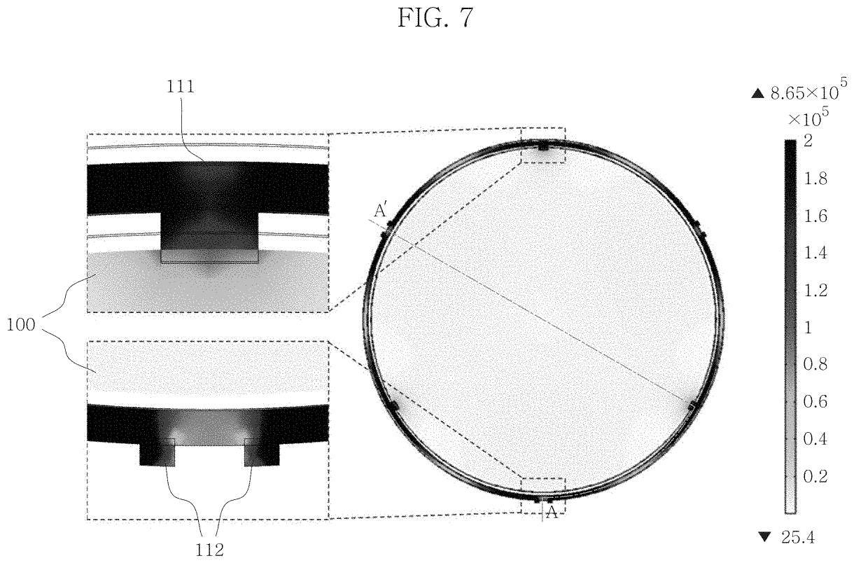

At the regions where spring structure 110 is connected to the first connecting part 111 and second connecting part 112 deformation occurs to a greater extent in response to the external sound pressure than in the other areas of spring structure 110. That is, the areas of spring structure 110 connected to first connecting part 111 and area of spring structure 110 connected to second connecting part 112 correspond to the maximum stress point. A detailed description will be provided based on FIGS. 7 to 9.

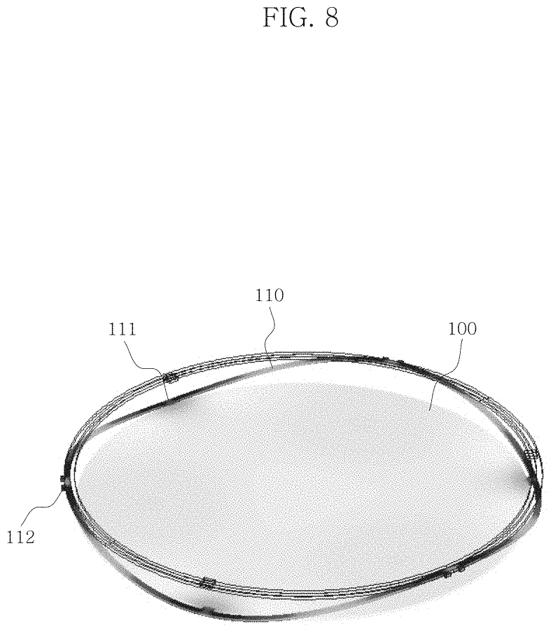

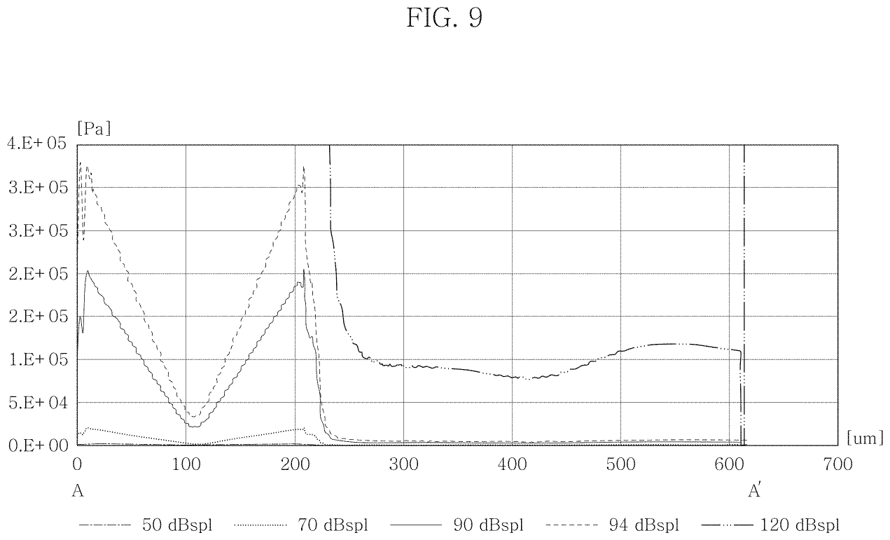

FIG. 7 shows the simulation results of the von-Mises stress distribution during the vibration of the membrane of the microphone according to the embodiment of the present disclosure. FIG. 8 shows the simulation results of the von-Mises stress distribution generated with the downward movement of membrane 100 of the microphone according to the embodiment of the present disclosure. FIG. 9 shows a graph of the change in the von-Mises stress observed in membrane 100 and spring structure 110 corresponding to A-A′ in FIG. 7 under a sound pressure of 50 dB spl to 120 dB spl inputted to the microphone.

FIGS. 7 and 8 show the von-Mises stress distribution and the extent of deformation of the microphone under the sound pressure of 94 dB spl on the simulation in which electrode 140 and insulation pattern 160 are omitted, while arc-shaped spring structure 110 is connected to anchor structure 150 and circular membrane 100.

FIG. 7 shows the stress distribution generated in membrane 100 and spring structure 110 when sound pressure is applied, and the area in black corresponds to an area in which strong stress are observed. As shown in FIG. 7, the maximum stress point is symmetrically positioned in the region around the connected part of spring structure 110 and first connecting part 111 and area around the connected part of spring structure 110 and second connecting part 112. These areas of spring structure 110 correspond to the region where tension and compression occur in an alternating manner via the piston motion of membrane 100. This can be seen from the stress distribution generated with the upward and downward movement of membrane 100. FIG. 8 shows that when membrane 100 moves below the reference position, the part of spring structure 110 connected to membrane 100 through first connecting part 111 moves down together with membrane 100, but the remaining part of spring structure 110 connected to anchor structure 150 through second connecting part 112 does not move and remains fixed. That is, a greater amount of compression-induced stress is generated near spring structure 110 connected to first connecting part 111 than the other areas. A greater amount of tension-induced stress is generated near spring structure 110 connected to second connecting part 112 than in the other areas. Piezoresistor 120 is located near spring structure 110 connected to first connecting part 111 and second connecting part 112, and it responds to the maximum deformation and exhibits a change in resistance with different polarities.

FIG. 9 shows the simulation results of the von-Mises stress on A-A′ across the membrane through spring structure 110 in microphone 10 according to this embodiment. In this simulation, the von-Mises stress distribution in spring structure 110 and membrane 100 under 50 dB spl of conversational speech level sound pressure to 120 dB spl of acoustic overload point level sound pressure of commercially available microphones is graphically visualized. Among all the structures that can deform in response to an external sound pressure because of the characteristics of flexible spring structure 110, the areas where spring structure 110 connected to first connecting part 111 and second connecting part 112 correspond to the maximum stress point, and the maximum deformation rate is observed in these regions.

In microphone 10 according to this embodiment, deformation caused by the external sound pressure occurs in flexible spring structure 110, and nanowire-based piezoresistor 120 is located near spring structure 110 corresponding to the maximum stress point. That is, according to the piezoresistive a property, piezoresistor 120 is positioned at the location where the maximum stress is generated, thereby realizing the maximum gauge change efficiency.

Additionally, microphone 10 according to this embodiment uses the characteristics that a change in resistance changes in polarity depending on the type of stress generated, and piezoresistor 120 is positioned at each of the maximum tension point and the maximum compression point of spring structure 110 to realize differential-mode signal measurement, thereby ensuring a high SRN.

Additionally, microphone 10 according to this embodiment may provide higher sensitivity by means of spring structure 110 without any increase in size of membrane 100. Thus, this embodiment may provide advantages in terms of minimization compared to the traditional microphone without any spring structure in which the entire outer periphery of the membrane is attached to the substrate.

While the present disclosure has been herein described with reference to the embodiments shown in the drawings, this is provided via illustrations. Those skilled in the art will understand that various modifications and variations may be made thereto. However, it should be understood that such modifications fall within the scope of technical protection of the present disclosure. Accordingly, the true technical protection scope of the present disclosure should be defined by the technical spirit of the appended claims.

What is claimed is:

1. A microphone comprising:
a membrane;
a spring structure that surrounds at least a part of the membrane, the spring structure spaced apart from the membrane;
at least one first connecting part that connects the membrane to the spring structure;
an anchor structure that surrounds at least a part of the spring structure, the anchor structure spaced apart from the spring structure;
at least one second connecting part that connects the anchor structure to the spring structure;
at least one piezoresistor formed on the spring structure; and
at least one electrode disposed on the anchor structure to sense an electrical signal from a change of the piezoresistor,
wherein the membrane, the spring structure, the first connecting part, and the second connecting part float in air by a cavity formed in the anchor structure.

2. The microphone according to claim 1, wherein deformation occurs in the membrane and the spring structure in response to sound pressure introduced from outside through the cavity, and the deformation occurs to a greater extent in the spring structure than in the membrane.

3. The microphone according to claim 2, wherein the first connecting part is connected to the spring structure and the membrane, and the second connecting part is connected to the spring structure and the anchor structure, to cause compression induced deformation and tension induced deformation to simultaneously occur in the spring structure in response to the sound pressure.

4. The microphone according to claim 3, wherein when the compression induced deformation occurs in an area of the spring structure connected to the first connecting part in response to the sound pressure, the tension induced deformation occurs together in an area of the spring structure connected to the second connecting part.

5. The microphone according to claim 4, wherein the piezoresistor includes a first piezoresistor and a second piezoresistor exhibiting changes in resistance with different polarities in response to the deformation of the spring structure,
the first piezoresistor is disposed in the area of the spring structure connected to the first connecting part, and
the second piezoresistor is disposed in the area of the spring structure connected to the second connecting part.

6. The microphone according to claim 5, wherein the electrode includes a first electrode configured to sense the deformation of the first piezoresistor and a second electrode configured to sense the deformation of the second piezoresistor, and
the first electrode and the second electrode output voltages having different polarities.

7. The microphone according to claim 6, wherein the microphone is configured to provide a single mode outputting deformation of one piezoresistor to which each electrode is electrically connected, or a differential mode using outputs of two different-polarity piezoresistors.

8. The microphone according to claim 1, wherein the piezoresistor is a silicon nanowire.

9. The microphone according to claim 1, wherein the membrane and the spring structure are formed of a silicon nitride layer or a composite layer including a silicon nitride layer and a dielectric thin film.
